(19) United States
(12) Patent Application Publication
(10) Pub. No.: US 2020/0058497 A1
(43) Pub. Date: Feb. 20, 2020

(54) Silicon nitride forming precursor control

(71) Applicant: Applied Materials, Inc, Santa Clara, CA (US)

(72) Inventors: Tae Kyung Won, San Jose, CA (US); Soo Young Choi, Fremont, CA (US); Jinhyun Cho, Santa Clara, CA (US); Yi Cui, San Jose, CA (US); Gaku Furuta, Sunnyvale, CA (US)

(21) Appl. No.: 15/999,206

(22) Filed: Aug. 20, 2018

(51) Int. Cl. H01L 21/02

(52) U.S. Cl. CPC H01L 21/02274; H01L 21/0217; H01L 21/02211

(57) ABSTRACT

Embodiments described herein relate to methods of controlling the uniformity of SiN films deposited over large substrates. When the precursor gas or gas mixture in the chamber is energized by applying radio frequency (RF) power to the chamber, the RF current flowing through the plasma generates a standing wave effect (SWE) in an inter-electrode gap. SWEs become significant as substrate or electrode size approaches the RF wavelength. Process parameters, such as process power, process pressure, electrode spacing, and gas flow ratios all affect the SWE. These parameters can be altered in order to minimize the SWE problem and to achieve acceptable thickness and properties uniformities. In some embodiments, methods of depositing a dielectric film over a large substrate at various process power ranges, at various process pressure ranges, at various gas flow rates, while achieving various plasma densities will act to reduce the SWE, creating greater plasma stability.

### BACKGROUND

### Field

Embodiments described herein generally relate to methods of controlling the uniformity of dielectric films deposited over substrates and, more particularly, SiN films deposited over large substrates.

### Description of the Related Art

Liquid crystal displays or flat panels are commonly used for active matrix displays such as computer and television monitors. Plasma enhanced chemical vapor deposition (PECVD) is generally employed to deposit thin films on a substrate such as a transparent substrate for flat panel display or semiconductor wafer. PECVD is generally accomplished by introducing a precursor gas or gas mixture into a vacuum chamber that contains a substrate. The precursor gas or gas mixture is typically directed downwardly through a distribution plate situated near the top of the chamber. The precursor gas or gas mixture in the chamber is energized (e.g., excited) into a plasma by applying radio frequency (RF) power to the chamber from one or more RF sources coupled to the chamber. The excited gas or gas mixture reacts to form a layer of material on a surface of the substrate that is positioned on a temperature controlled substrate support. Volatile by-products produced during the reaction are pumped from the chamber through an exhaust system.

Flat panels processed by PECVD techniques are typically large. As the size of substrates continues to grow in the TFT-LCD industry, film thickness and film property uniformity control for large area PECVD becomes an issue. For example, the difference of deposition rate and/or film property, such as film stress, between the center and the edge of the substrate becomes significant. As the size of substrates continues to grow in the TFT-LCD industry, film thickness and property uniformity for large area PECVD becomes more problematic. Examples of noticeable uniformity problems include higher deposition rates and more compressive films in the central area of large substrates for some high deposition rate SiN films. The thickness uniformity across the substrate appears “dome shaped”, or “center thick”, with the film in the center region thicker than the edge region. Larger substrates have worse center thick uniformity issues.

Accordingly, there is a need in the art to improve the uniformity of film deposition thickness and film properties for thin films, particularly SiN films that are deposited on large substrates in PECVD chambers.

### SUMMARY

One or more embodiments described herein related to methods for depositing SiN films over large substrates.

In one embodiment, a method of depositing a dielectric film over a substrate having a surface area larger than about 9 m² includes depositing the dielectric film at a power in a process chamber that is from a power density of between about 0.25 W/cm2 to about 0.35 W/cm2; depositing the dielectric film at a process pressure that is between about 1.0 Torr to about 1.5 Torr; and depositing the dielectric film from precursors including N₂, NH₃, and SiH₄, wherein a flow ratio of NH₃/SiH₄ is between about 1.5 to about 9, a flow ratio of N₂/SiH₄ is between about 2.0 to about 6.0, a flow ratio of N₂/NH₃ is between about 0.4 to about 2.0.

In another embodiment, a method of depositing a dielectric film over a substrate having a surface area larger than about 9 m² includes depositing the dielectric film at a process power density that is between about 0.25 W/cm² to about 0.35 W/cm²; depositing the dielectric film at a process pressure that is between about 1.3 Torr to about 1.5 Torr; and depositing the dielectric film from precursors including N₂, NH₃, and SiH₄, wherein a flow ratio of NH₃/SiH₄ is between about 1.5 to about 7.0, a flow ratio of N₂/SiH₄ is between about 2.0 to about 5.0, a flow ratio of N₂/NH₃ is between about 0.4 to about 2.0.

In another embodiment, a method of depositing a dielectric film over a substrate having a surface area larger than about 9 m² includes depositing the dielectric film at a process power that is between 0.30 W/cm² to about 0.35 W/cm²; depositing the dielectric film at a process pressure that is between about 1.3 Torr to about 1.5 Torr; and depositing the dielectric film from precursors including N₂, NH₃, and SiH₄, wherein a flow ratio of NH₃/SiH₄ is between about 2.0 to about 4.5, a flow ratio of N₂/SiH₄ is between about 2.0 to about 4.0, a flow ratio of N₂/NH₃ is between about 0.6 to about 2.0.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a schematic cross-sectional view of a system according to at least one embodiment of the present disclosure;

FIG. 2 is a partial sectional view of the exemplary diffuser plate according to FIG. 1; and

FIG. 3 is a flow chart of a method according to at least one embodiment of the present disclosure.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

In the following description, numerous specific details are set forth to provide a more thorough understanding of the embodiments of the present disclosure. However, it will be apparent to one of skill in the art that one or more of the embodiments of the present disclosure may be practiced without one or more of these specific details. In other instances, well-known features have not been described in order to avoid obscuring one or more of the embodiments of the present disclosure.

Embodiments described herein generally relate to methods of controlling the uniformity of dielectric films deposited over substrates and, more particularly, SiN films deposited over large area substrates. As PECVD systems deposit thin films on a substrate, precursor gas or gas mixture is typically directed downwardly through a distribution plate situated near the top of the chamber. When the precursor gas or gas mixture in a large area substrate processing chamber is energized by applying RF power to the chamber from one or more RF sources coupled to a bias able chamber component, the RF current flowing through the plasma generates a standing wave effect (SWE) in an inter-electrode gap. SWEs manifest themselves most clearly as a dome or increase in film thickness at the center of the substrate. SWEs become significant as substrate or electrode size approaches the RF wavelength. Increasing the wavelength by lowering the RF frequency is undesirable because higher plasma potential (as indicated by peak-to-peak voltage) induces ion bombardment which may damage the substrate and films. For other reasons, such as, but not limited to, increasing the deposition rate, RF frequencies may be increased, only exacerbating the standing wave effect. Therefore, robust solutions to the SWE problem and large substrate problems must be found.

If has been found that process parameters, such as process power, process pressure, electrode spacing, and gas flow ratios all affect the SWE. These parameters can be altered in order to minimize the SWE problem and to achieve acceptable thickness and properties uniformities. In some embodiments, methods of depositing a dielectric film over a large substrate at various process power ranges, at various process pressure ranges, at various gas flow rates, while achieving various plasma densities, will act to reduce the SWE, creating greater plasma stability. Using these process parameters will help mitigate or eliminate the problem of the film thickness being higher at the center region than at the edge region of substrates due to the SWE, and result in a more uniform film thickness across entire substrate. These parameters and ranges will be discussed in more detail herein.

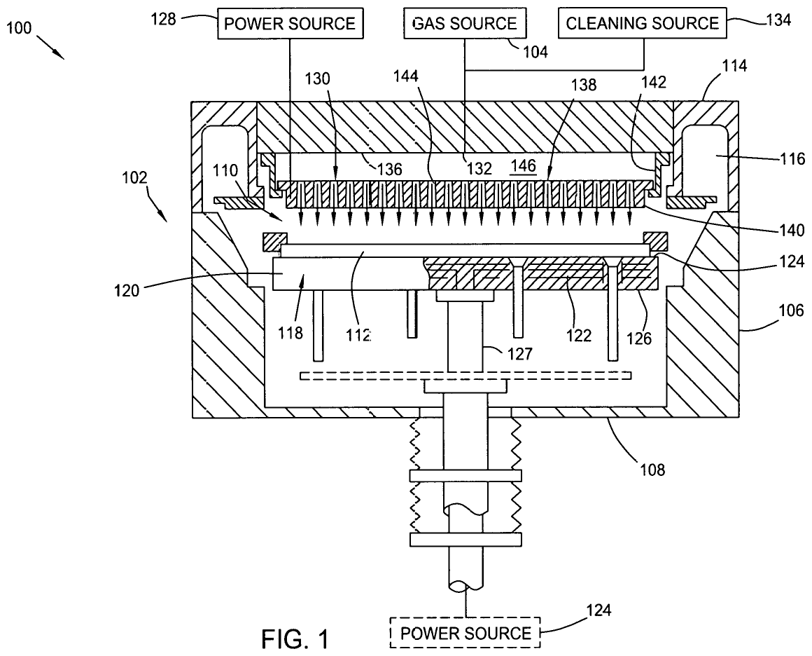

FIG. 1 is a schematic cross-sectional view of a system 100 according to at least one embodiment of the present disclosure. The system 100 is generally a PECVD system, but can be other suitable systems as well. The system 100 generally includes a processing chamber 102 coupled to a gas source 104. The processing chamber 102 has walls 106 and a bottom 108 that partially define a process volume 110. The process volume 110 is typically accessed through a port (not shown) in the walls 106 that facilitate movement of a substrate 112 into and out of the processing chamber 102. The walls 106 and bottom 108 may be fabricated from a unitary block of aluminum or other material compatible with processing. The walls 106 support a lid assembly 114 that contains a pumping plenum 116 that couples the process volume 110 to an exhaust port (that includes various pumping components, not shown). Alternatively, an exhaust port (not shown) is located in the floor of processing chamber 102 and process volume 110 does not require a pumping plenum 116.

A temperature controlled support assembly 118 is centrally disposed within the processing chamber 102. The support assembly 118 supports the substrate 112 during processing. In one embodiment, the support assembly 118 comprises a body 120 that encapsulates at least one embedded heater 122. The heater 122, such as a resistive element, disposed in the support assembly 118, is coupled to an optional power source 124 and controllably heats the support assembly 118 and the substrate 112 positioned thereon to a predetermined temperature. Typically, in a CVD process, the heater 122 maintains the substrate 112 at a uniform temperature between about 120 to at least about 460 degrees Celsius, depending on the deposition processing parameters for the material being deposited.

Generally, the support assembly 118 has an upper side 124 and a lower side 126. The upper side 126 supports the substrate 112. The lower side 126 has a stem 127 coupled thereto. The stem 127 couples the support assembly 118 to a lift system (not shown) that moves the support assembly 118 between an elevated processing position (as shown) and a lowered position that facilitates substrate transfer to and from the processing chamber 102. The stem 127 additionally provides a conduit for electrical and thermocouple leads between the support assembly 118 and other components of the system 100.

The support assembly 118 is generally grounded such that RF power supplied by a power source 128 to a gas distribution plate assembly 130 positioned between the lid assembly 114 and support assembly 118 (or other electrode positioned within or near the lid assembly of the chamber) may excite gases present in the process volume 110 between the support assembly 118 and the gas distribution plate assembly 130. The RF power from the power source 128 is generally selected commensurate with the size of the substrate to drive the chemical vapor deposition process.

The lid assembly 114 provides an upper boundary to the process volume 110. In one embodiment, the lid assembly 114 is fabricated from aluminum (Al). The lid assembly 114 includes a pumping plenum 116 formed therein coupled to an external pumping system (not shown). The pumping plenum 116 is utilized to channel gases and processing by-products uniformly from the process volume 110 and out of the processing chamber 102. The lid assembly 114 typically includes an entry port 132 through which process gases provided by the gas source 104 are introduced into the processing chamber 102. The entry port 132 is also coupled to a cleaning source 134. The cleaning source 134 typically provides a cleaning agent, such as dissociated fluorine, that is introduced into the processing chamber 102 to remove deposition by-products and films from processing chamber hardware, including the gas distribution plate assembly 130.

The gas distribution plate assembly 130 is coupled to an interior side 136 of the lid assembly 114. The shape of gas distribution plate assembly 130 is typically configured to substantially conform to the perimeter of the substrate 112, for example, polygonal for large area flat panel substrates and circular for wafers. The gas distribution plate assembly 130 includes a perforated area 138 through which process and other gases supplied from the gas source 104 are delivered to the process volume 110. The perforated area 138 of the gas distribution plate assembly 130 is configured to provide uniform distribution of gases passing through the gas distribution plate assembly 130 into the processing chamber 102. The gas distribution plate assembly 130 typically includes a diffuser plate 140 suspended from a hanger plate 142. The diffuser plate 140 and hanger plate 142 may alternatively comprise a single unitary member. A plurality of gas passages 144 are formed through the diffuser plate 140 to allow a predetermined distribution of gas to pass through the gas distribution plate assembly 130 and into the process volume 110. A plenum 146 is formed between hanger plate 142, diffuser plate 140 and the interior surface 136 of the lid assembly 114. The plenum 146 allows gases flowing through the lid assembly 114 to uniformly distribute across the width of the diffuser plate 140 so that gas is provided uniformly above the perforated area 138 and flows with a uniform distribution through the gas passages 144.

The diffuser plate 140 is typically fabricated from stainless steel, aluminum (Al), nickel (Ni) or other RF conductive material. The diffuser plate 140 could be cast, brazed, forged, hot iso-statically pressed or sintered. In one embodiment, the diffuser plate 140 is fabricated from bare, non-anodized aluminum. A non-anodized aluminum surface for diffuser plate 140 has been shown to reduce the formation of particles thereon that may subsequently contaminate substrates processed in the system 100. Additionally, the manufacturing cost of diffuser plate 140 is reduced when it is not anodized. The diffuser plate 140 could be circular for semiconductor wafer manufacturing or polygonal, such as rectangular, for flat panel display manufacturing.

Typically, it was standard practice in the art for diffuser plate 140 to be configured substantially flat and parallel to substrate 112 and for the distribution of identical gas passages 144 to be substantially uniform across the surface of diffuser plate 140. Such a configuration of the diffuser plate 140 has provided adequate gas flow and plasma density uniformity in process volume 110 for depositing films on smaller substrates. As substrates increase in size, however, the uniformity of deposited films—especially SiN films—has become more difficult to maintain. The diffuser plate 140 with a uniform distribution of gas passages 144 of uniform size and shape is generally not able to deposit films with acceptable thickness and film property uniformity onto large area substrates. It has been shown that for a SiN film deposited on a larger substrate, the film thickness and film property uniformity can be improved by use of a hollow cathode gradient (HCG) described below.

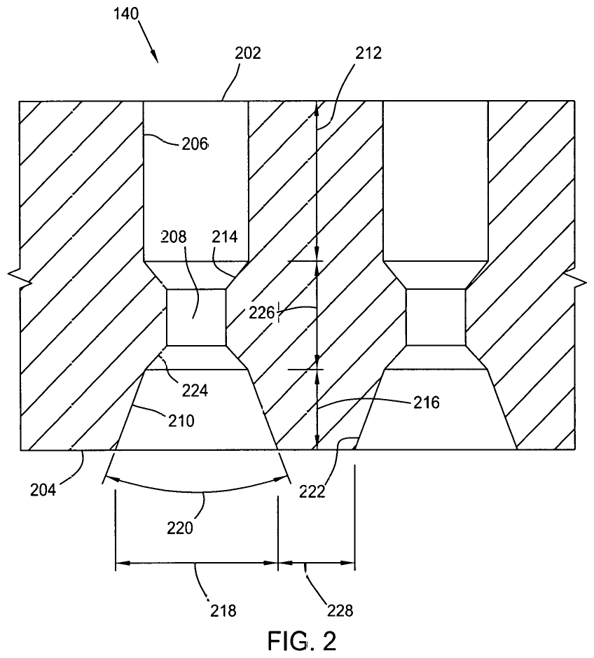

FIG. 2 is a partial sectional view of a portion of the diffuser plate 140 of FIG. 1 that includes a HCG. The diffuser plate 140 includes a first or upstream side 202 facing the lid assembly 114 and an opposing second or downstream side 204 that faces the support assembly 118. Each gas passage 144 is defined by a first bore 206 coupled by an orifice hole 208 to a second bore 210 that combine to form a fluid path through the gas distribution plate assembly 130. The first bore 206 extends a first depth 212 from the upstream side 202 of the gas distribution plate assembly 130 to a bottom 214. The bottom 214 of the first bore 206 may be tapered, beveled, chamfered or rounded to minimize the flow restriction as gases flow from the first bore into the orifice hole 208. The first bore 206 generally has a diameter of about 0.093 to about 0.218 inches, and in one embodiment is about 0.156 inches.

The second bore 210 is formed in the diffuser plate 140 and extends from the downstream side (or end) 204 to a depth 216 of about 0.10 inch to about 2.0 inches. Preferably, the depth 216 is between about 0.1 inch to about 1.0 inch. The opening diameter 218 of the second bore 210 is generally about 0.1 inch to about 1.0 inch and may be flared at a flaring angle 220 of about 10 degrees to about 50 degrees. Preferably, the opening diameter 218 is between about 0.1 inch to about 0.5 inch and the flaring angle 220 is between 20 degrees to about 40 degrees. The surface area of the second bore 210 is between about 0.05 inch² to about 10 inch² and preferably between about 0.05 inch² to about 5 inch². The diameter of second bore 210 refers to the diameter intersecting the downstream surface 204. An example of a diffuser plate 140 used to process large substrates has second bores 210 at a diameter of 0.302 inch and at a flaring angle 220 of about 22 degrees. The distances 228 between rims 222 of adjacent second bore 210 are between about 0 inches to about 0.6 inches, preferably between about 0 Inches to about 0.4 inches. The diameter of the first bore 206 is usually, but not limited to, being at least equal to or smaller than the diameter of the second bore 210. A bottom 224 of the second bore 210 may be tapered, beveled, chamfered or rounded to minimize the pressure loss of gases flowing out from the orifice hole 208 and into the second bore 210. Moreover, as the proximity of the orifice hole 208 to the downstream side 204 serves to minimize the exposed surface area of the second bore 210 and the downstream side 204 that face the substrate, the downstream area of the diffuser plate 140 exposed to fluorine provided during chamber cleaning is reduced, thereby reducing the occurrence of fluorine contamination of deposited films.

The orifice hole 208 generally couples the bottom 214 of the first bore 206 and the bottom 224 of the second bore 210. The orifice hole 208 generally has a diameter of about 0.01 inch to about 0.3 inch, preferably about 0.01 inch to about 0.1 inch, and typically has a length 226 of about 0.02 inch to about 1.0 inch, preferably about 0.02 inch to about 0.5 inch. The length 226 and diameter (or other geometric attribute) of the orifice hole 208 is the primary source of back pressure in the plenum 146 which promotes even distribution of gas across the upstream side 202 of the gas distribution plate assembly 130. The orifice hole 208 is typically configured uniformly among the plurality of gas passages 144; however, the restriction through the orifice hole 208 may be configured differently among the gas passages 144 to promote more gas flow through one area of the gas distribution plate assembly 130 relative to another area. For example, the orifice hole 208 may have a larger diameter and/or a shorter length 226 in those gas passages 144, of the gas distribution plate assembly 130, closer to the walls 106 of the processing chamber 102 so that more gas flows through the edges of the perforated area 138 to increase the deposition rate at the perimeter of the substrate. The thickness of the diffuser plate 140 is between about 0.8 inch to about 3.0 inches, preferably between about 0.8 inch to about 2.0 inch.

Using the design in FIG. 2 as an example, the volume of second bore 210 can be changed by varying the opening diameter 218, the depth 216, and/or the flaring angle 220. Changing the diameter, depth and/or the flaring angle would also change the surface area of the second bore 210. It is believed that higher plasma density is likely the cause of the higher deposition rate at the center of substrate 112 (shown in FIG. 1). By reducing the bore depth 216, the diameter, the flaring angle 220, or a combination of these three parameters from edge to center of the diffuser plate 140, the plasma density can be reduced in the center region of the substrate to improve the uniformity of film thickness and film properties. For example, one way to improve film properties is to design the downstream surface 204 of the diffuser plate 140 to have a concave shape. In this case, the apex can be located approximately over the center point of the substrate 112, with the electrode spacing increasing from the edge of the diffuser plate 140 to the center.

Although the HCG design as described in FIG. 2 helps improve film uniformity, greater improvements are achieved by carefully controlling the process parameters used in production of the SiN gate dielectric film, especially on large substrates. Using the following processing parameters will help mitigate or reduce the problem of the film thickness being higher at the center region than at the edge region of the substrate 112, and result in a more uniform film thickness across the entire substrate 112, extending to its edges.

For example, it is believed that using a higher flow rate of NH₃ gas versus N₂ is useful since the weak N—H bond strength in the NH₃ gas allows a lower power to be applied to dissociate the nitrogen and hydrogen elements. Lower process power helps to improve plasma stability and to mitigate the SWE. The table below contains processing parameters which can be applied during the deposition of a SiN film across large area substrates.

TABLE 1

| Parameter | Range | |
|---|---|---|
| Power Density | 0.25-0.35 | W/cm² |
| Pressure | 1.0-1.5 | Torr |
| Temperature | 120-340 | degrees Celsius |
| Electrode to Substrate Spacing | 900-1000 | mils |
| SiH₄ flow rate | 0.05-0.1 | sccm/cm² |
| NH₃ flow rate | 0.1-0.7 | sccm/cm² |
| N₂ flow rate | 0.1-0.8 | sccm/cm² |
| N₂/NH₃ ratio | 0.4-2.0 | |
| total gas/SiH₄ ratio | 6.0-17.0 | |
| NH₃/SiH₄ ratio | 2.0-9.0 | |
| N₂/SiH₄ ratio | 2.0-11.0 | |
| (NH₃ + N₂)/SiH₄ ratio | 5.0-16.0 | |
| N₂/power | 0.4-1.2 | sccm/W |
| NH₃/power | 0.4-2.0 | sccm/W |
| SiH₄/power | 0.2-0.3 | sccm/W |

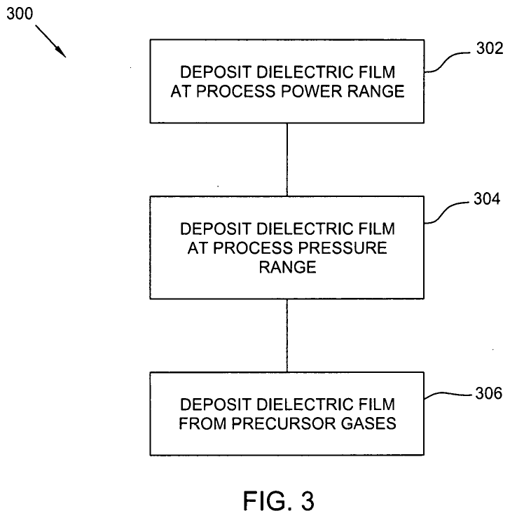

FIG. 3 is a flow chart illustrating a method 300 according to at least one embodiment of the present disclosure. It has been found that each block found in method 300 is particularly useful for depositing dielectric films over substrates having a surface area larger than about 9 m², however other substrate sizes with larger or smaller surface areas can be used.

In block 302, the dielectric film is deposited at a certain process power range. As shown in Table 1, the process power density range can be between about 0.25 watts (W)/cm² to about 0.35 W/cm², preferably between 0.30 W/cm² and 0.35 W/cm², although other ranges are possible. Power at these ranges when compared with various gases at various flow rates can provide film substrates with greater uniformity, which will be discussed in more detail in block 306.

In block 304, the dielectric film is deposited at a process pressure. As also shown in Table 1, the process pressure can range between about 1.0 Torr to about 1.5 Torr, preferably between 1.3 Torr and 1.5 Torr, although other ranges are possible. Much like power, pressure at these ranges when compared with various gases at various flow rates can provide film substrates with greater uniformity, which will be discussed in more detail in block 306.

In block 306, the dielectric film is deposited from precursor gases. In some embodiments, the precursor gases include N₂, NH₃, and SiH₄, however other precursor gases are also possible. As shown in Table 1, the precursor gases have various flow rate ranges. Various gases provided at various flow rates, when combined with other process parameters in the process ranges, can act to provide desired film results. For example, various flow ratios of N₂/NH₃, NH₃/SiH₄, N₂/SiH₄ can be combined at various process powers and pressures to create desired results. Changing any one parameter can change an undesired film result to a desired film result. In some embodiments, the precursors provided during processing include N₂, NH₃, and SiH₄, wherein a flow ratio of NH₃/SiH₄ is between about 1.5 to about 9, a flow ratio of N_{2/}SiH₄ is between about 2.0 to about 6.0, and a flow ratio of N₂/NH₃ is between about 0.4 to about 2.0. In another embodiment, the precursors provided during processing include N₂, NH₃, and SiH₄, wherein at least one of the flow ratios are selected from the following: a flow ratio of NH₃/SiH₄ is between about 2.0 to about 4.5, a flow ratio of N_{2/}SiH₄ is between about 2.0 to about 4.0, and a flow ratio of N₂/NH₃ is between about 0.6 to about 2.0. In yet another embodiment, the precursors provided during processing include N₂, NH₃, and SiH₄, wherein at least one of the flow ratios are selected from the following: a flow ratio of NH₃/SiH₄ is between about 2.3 to about 4.4; a flow ratio of N_{2/}SiH₄ is between about 2.6 to about 4.0; and a flow ratio of N₂/NH₃ is between about 0.6 to about 1.0.

For example, in one embodiment, SiH₄ flow rates can range between about 0.05 sccm/cm² to about 0.07 sccm/cm²; process power density can vary between about 0.30 W/cm² to about 0.35 W/cm²; and process pressure can vary between about 1.3 Torr to about 1.5 Torr to get desired results. In another embodiment, a process power density can range between about 0.30 W/cm² to about 0.35 W/cm²; process pressure can vary between about 1.3 Torr to about 1.5 Torr; and the temperature in the processing chamber 102 can vary between about 240 to about 320 degrees Celsius to get desired results. In another embodiment, SiH₄ flow rates can range between about 0.05 sccm/cm² to about 0.07 sccm/cm²; process power density can vary between about 0.30 W/cm² to about 0.35 W/cm²; process pressure can vary between about 1.3 Torr to about 1.5 Torr; and the temperature in the processing chamber 102 between about 240 to about 320 degrees Celsius to get desired results. In another embodiment, a process power density can range between about 0.30 W/cm² to about 0.35 W/cm²; process pressure can vary between about 1.3 Torr to about 1.5 Torr; the temperature in the processing chamber 102 can vary between about 240 to about 320 degrees Celsius; and the electrode spacing at the center of the substrate 112 to the diffuser plate 140 can vary between about 900 mils to about 1000 mils to get desired results. In another embodiment, SiH₄ flow rates can range between about 0.05 sccm/cm² to about 0.07 sccm/cm²; process power density can vary between about 0.30 W/cm² to about 0.35 W/cm²; process pressure can vary between about 1.3 Torr to about 1.5 Torr; the temperature in the processing chamber 102 can vary between about 240 to about 320 degrees Celsius; and the electrode spacing at the center of the substrate 112 to the diffuser plate 140 can vary between about 900 mils to about 1000 mils to get desired results. The above embodiments only represent some of many examples of process parameters within the ranges provided in Table 1 that can be used to form a film having desirable properties. In one embodiment, the desired result achieved in these examples and in block 306, is to mitigate or eliminate the problem of the film thickness being higher at the center region versus at the edge region of the substrate 112, and results in a more uniform film thickness across the entire substrate 112.

Each of the blocks in method 300 acts to improve film uniformity, while also maintaining plasma stability and helping mitigate the SWE. More specifically, the method 300 helps mitigate or eliminate the problem of the film thickness being higher at the center region than at the edge region of the substrate 112, and results in a more uniform film thickness across the entire substrate 112, from the center region to the edges due to the SWE. This is especially important for large substrates and processing chambers.

While the foregoing is directed to embodiments of the present disclosure, other and further embodiments of the disclosure may be devised without departing from the basic scope thereof, and the scope thereof is determined by the claims that follow.

1. A method of depositing a dielectric film over a substrate having a surface area larger than about 9 m², comprising:
depositing the dielectric film at a process power, wherein the process power is provided at a power density of between about 0.25 W/cm² to about 0.35 W/cm²;
depositing the dielectric film at a process pressure that is between about 1.0 Torr to about 1.5 Torr; and
depositing the dielectric film from precursors including N₂, NH₃, and SiH₄, wherein a flow ratio of NH₃/SiH₄ is between about 1.5 to about 9, a flow ratio of N_{2/}SiH₄ is between about 2.0 to about 6.0, and a flow ratio of N₂/NH₃ is between about 0.4 to about 2.0.

2. The method of claim 1, wherein an electrode spacing in the process chamber is between about 900 mils to about 1000 mils.

3. The method of claim 1, wherein the process pressure is between about 1.3 Torr to about 1.5 Torr.

4. The method of claim 1, wherein the process power density is between about 0.25 W/cm² to about 0.35 W/cm².

5. The method of claim 1, wherein the substrate is at a temperature ranging between about 120 degrees Celsius to about 340 degrees Celsius.

6. The method of claim 5, wherein the temperature range is between about 240 degrees Celsius to about 320 degrees Celsius.

7. A method of depositing a dielectric film over a substrate having a surface area larger than about 9 m², comprising:
depositing the dielectric film at a process power, wherein the process power is provided at a power density that is between about 0.25 W/cm² to about 0.35 W/cm²;
depositing the dielectric film at a process pressure that is between about 1.3 Torr to about 1.5 Torr; and
depositing the dielectric film from precursors including N₂, NH₃, and SiH₄, wherein a flow ratio of NH₃/SiH₄ is between about 1.5 to about 7.0, a flow ratio of N₂/SiH₄ is between about 2.0 to about 5.0, and a flow ratio of N₂/NH₃ is between about 0.4 to about 2.0.

8. The method of claim 7, wherein an electrode spacing in the process chamber is between about 900 mils to about 1000 mils.

9. The method of claim 7, wherein the process power density is between about 0.30 W/cm² to about 0.35 W/cm².

10. The method of claim 7, wherein the substrate is at a temperature between about 120 degrees Celsius to about 340 degrees Celsius.

11. The method of claim 10, wherein the temperature is between about 240 degrees Celsius to about 320 degrees Celsius.

12. A method of depositing a dielectric film over a substrate having a surface area larger than about 9 m², comprising:
depositing the dielectric film at a first process power, wherein the first process power is provided at a power density that is between 0.30 W/cm² to about 0.35 W/cm²;
depositing the dielectric film at a process pressure that is between about 1.3 Torr to about 1.5 Torr; and
depositing the dielectric film from precursors including N₂, NH₃, and SiH₄, wherein a flow ratio of NH₃/SiH₄ is between about 2.0 to about 4.5, a flow ratio of N₂/SiH₄ is between about 2.0 to about 4.0, a flow ratio of N₂/NH₃ is between about 0.6 to about 2.0.

13. The method of claim 12, wherein an electrode spacing in the process chamber is between about 900 mils to about 1000 mils.

14. The method of claim 12, wherein the process power density is between about 0.30 W/cm² to about 0.35 W/cm².

15. The method of claim 14, wherein the substrate is at a temperature ranging between about 120 degrees Celsius to about 340 degrees Celsius.

16. The method of claim 15, wherein the temperature is between about 240 degrees Celsius to about 320 degrees Celsius.

17. The method of claim 12, wherein the flow ratio of NH₃/SiH₄ is between about 4.0 to about 4.5.

18. The method of claim 12, wherein the flow ratio of N₂/SiH₄ is between about 2.4 to about 2.6.

19. The method of claim 12, wherein the flow ratio of N₂/NH₃ is between about 1.0 to about 2.0.
